(19) United States
(12) Patent Application Publication
(10) Pub. No.: US 2019/0181320 A1
(43) Pub. Date: Jun. 13, 2019

(54) ELECTRIC GENERATOR AND METHOD OF MAKING THE SAME

(71) Applicant: PURDUE RESEARCH FOUNDATION, West Lafayette, IN (US)

(72) Inventors: Kazuaki Yazawa, West Lafayette, IN (US); Ali Shakouri, West Lafayette, IN (US)

(73) Assignee: PURDUE RESEARCH FOUNDATION, West Lafayette, IN (US)

(21) Appl. No.: 16/219,882

(22) Filed: Dec. 13, 2018

Related U.S. Application Data
(60) Provisional application No. 62/598,281, filed on Dec. 13, 2017.

(51) Int. Cl. H01L 35/24; H01L 35/34

(52) U.S. Cl. CPC H01L 35/24; H01L 35/34

(57) ABSTRACT

An electric generator including a thermoelectric material over a first metallization surface. The thermoelectric material includes at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film. Additionally, the electric generator includes a second metallization surface over the thermoelectric material.

### CROSS-REFERENCE TO RELATED APPLICATIONS

The present U.S. Patent Application is related to and claims the priority benefit of U.S. Provisional Patent Application Ser. No. 62/598,281, filed Dec. 13, 2017, the contents of which is hereby incorporated by reference in its entirety into this disclosure.

### BACKGROUND

Although inorganic materials generally exhibit high performance in thermoelectric devices, these materials are typically expensive and are characterized by brittleness, which renders their application in large areas difficult.

### SUMMARY

Organic materials have unique advantages as thermoelectric materials, such as cost effectiveness, low intrinsic thermal conductivity, high flexibility, and amenability to large area applications. Various embodiments of the present application relate to an electric generator which incorporates various thermoelectric materials.

One aspect of the present disclosure includes an electric generator including a thermoelectric material over a first metallization surface. The thermoelectric material includes at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film. Additionally, the electric generator includes a second metallization surface over the thermoelectric material.

Another aspect of the present disclosure includes an electric generator. The electric generator includes a thermoelectric material over a first metallization surface. The thermoelectric material includes at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film. The electric generator additionally includes a second metallization surface over the thermoelectric material. Additionally, the electric generator includes a second thermoelectric material between the thermoelectric material and the first metallization surface. The second thermoelectric material has a porosity less than the porosity of the thermoelectric material. The second thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film. Further, the electric generator includes a third thermoelectric material between the thermoelectric material and the first metallization surface. The third thermoelectric material has a porosity less than the porosity of the thermoelectric material. The third thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film.

The first metallization surface over a first substrate. Additionally, the electric generator includes a second substrate over the second metallization surface. The thermoelectric material comprises a porosity ranging from 50% to 90%. A thickness of the thermoelectric material ranges from approximately 1 micrometer to approximately 5 millimeters. The polyimide film has a thermal conductivity ranging from approximately 0.1 W/m/K to approximately 1.5 W/m/K. A thickness of the second thermoelectric material ranges from approximately 1 micrometer to approximately 5 millimeters. A thickness of the third thermoelectric material ranges from approximately 1 micrometer to approximately 5 millimeters.

Still another aspect of the present disclosure includes an electric generator. The electric generator includes a thermoelectric material over a first metallization surface. The thermoelectric material includes at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi2Te3), or a polyimide film. The electric generator additionally includes a second metallization surface over the thermoelectric material. Additionally, the electric generator includes a second thermoelectric material between the thermoelectric material and the first metallization surface. The second thermoelectric material has a porosity less than the porosity of the thermoelectric material. The second thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film. Further, the electric generator includes a third thermoelectric material between the thermoelectric material and the first metallization surface. The third thermoelectric material has a porosity less than the porosity of the thermoelectric material. The third thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film.

The thermoelectric material comprises a porosity ranging from 50% to 90%. A thickness of the thermoelectric material ranges from approximately 1 micrometer to approximately 5 millimeters. The polyimide film has a thermal conductivity ranging from approximately 0.1 W/m/K to approximately 1.5 W/m/K. A thickness of the second thermoelectric material ranges from approximately 1 micrometer to approximately 5 millimeters. A thickness of the third thermoelectric material ranges from approximately 1 micrometer to approximately 5 millimeters.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. It is emphasized that, in accordance with standard practice in the industry, various features may not be drawn to scale and are used for illustration purposes only. In fact, the dimensions of the various features in the drawings may be arbitrarily increased or reduced for clarity of discussion.

FIG. 1 is a cross-sectional view of an electric generator in accordance with one or more embodiments.

FIG. 2 is a flow chart of a method of making an electric generator in accordance with one or more embodiments.

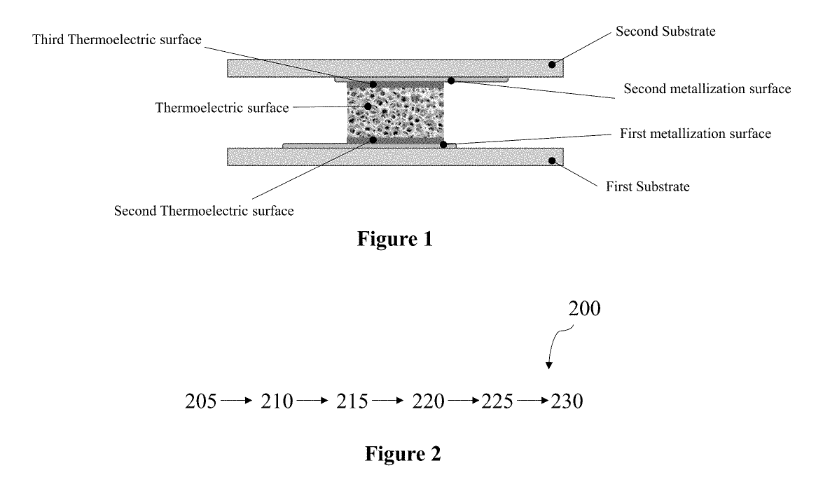

### DETAILED DESCRIPTION

The following disclosure provides many different embodiments, or examples, for implementing different features of the present application. Specific examples of components and arrangements are described below to simplify the present disclosure. These are examples and are not intended to be limiting. The making and using of illustrative embodiments are discussed in detail below. It should be appreciated, however, that the disclosure provides many applicable concepts that can be embodied in a wide variety of specific contexts. In at least some embodiments, one or more embodiment(s) detailed herein and/or variations thereof are combinable with one or more embodiment(s) herein and/or variations thereof.

An electric generator includes a thermoelectric material over a first metallization surface, and a second metallization surface over the thermoelectric material. In various embodiments, the thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film.

In one or more embodiments, the thermoelectric material includes a porosity ranging from 50% to 90%. In at least one embodiment, a thickness of the thermoelectric material ranges from approximately 1 micrometer to approximately 5 millimeters.

In some embodiments, the first metallization surface over a first substrate, and a second substrate is over the second metallization surface. In at least one embodiment, the polyimide film has a thermal conductivity ranging from approximately 0.1 W/m/K to approximately 1.5 W/m/K. In some embodiments, the polyimide film has a thermal conductivity greater than approximately 0.5 W/m/K.

According to at least one embodiment, the electric generator further includes a second thermoelectric material between the thermoelectric material and the first metallization surface. The second thermoelectric material has a porosity less than the porosity of the thermoelectric material. In one or more embodiments, the second thermoelectric material includes at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nano structured particles embedded in a base polymer, Bismuth telluride (Bi₂Te₃), or a polyimide film. In at least one embodiment, the second thermoelectric material has almost no porosity. In some embodiments, the second thermoelectric material has no porosity.

In some embodiments, a thickness of the second thermoelectric material is approximately 100 microns. In at least one embodiment, a thickness of the second thermoelectric material ranges approximately from 1 micrometer to approximately 5 millimeters.

According to at least one embodiment, the electric generator further includes a third thermoelectric material between the thermoelectric material and the second metallization surface. The third thermoelectric material has a porosity less than the porosity of the thermoelectric material. In one or more embodiments, the third thermoelectric material includes at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film. In at least one embodiment, the third thermoelectric material has almost no porosity. In some embodiments, the third thermoelectric material has no porosity.

In some embodiments, a thickness of the third thermoelectric material is approximately 100 microns. In at least one embodiment, a thickness of the third thermoelectric material ranges approximately from 1 micrometer to approximately 5 millimeters. In one or more embodiments, a monolithic thermoelectric material includes the thermoelectric material, the second thermoelectric material, and the third thermoelectric material.

FIG. 2 is a flow chart of a method of making an electric generator in accordance with one or more embodiments. Method 200 begins with operation 205 in which a first substrate is provided. In at least one embodiment, the first substrate is formed using a metalorganic chemical vapor deposition (MOCVD) process. In some embodiments, the first substrate is formed using molecular beam epitaxy (MBE), hydride vapor phase epitaxy (HVPE), or other suitable formation method. The MOCVD process includes introducing precursors into a process environment and providing conditions which promote a reaction between appropriate atoms in the precursors to form a first substrate.

Method 200 continues with operation 210 where a first metallization surface is formed over the first substrate. In at least one embodiment, the first metallization is formed using a metalorganic chemical vapor deposition (MOCVD) process. In some embodiments, the first metallization surface is formed using molecular beam epitaxy (MBE), hydride vapor phase epitaxy (HVPE), Physical Vapor Deposition (PVD), Chemical Vapor Deposition (CVD), Atomic Layer Deposition (ALD), sputtering, spin-on coating or another suitable formation method.

Method 200 continues with operation 215 where a first side of a monolithic thermoelectric material is mechanically placed onto the first metallization surface. In various embodiments, the monolithic thermoelectric material includes the thermoelectric material, the second thermoelectric material, and the third thermoelectric material. In one or more embodiments, the monolithic thermoelectric material is electrically contacted to the first metallization surface by soldering or welding the second thermoelectric material to the first metallization surface.

Method 200 continues with operation 220 in which a second substrate is provided. In at least one embodiment, the second substrate is formed using a metalorganic chemical vapor deposition (MOCVD) process. In some embodiments, the second substrate is formed using molecular beam epitaxy (MBE), hydride vapor phase epitaxy (HVPE), or other suitable formation method. The MOCVD process includes introducing precursors into a process environment and providing conditions which promote a reaction between appropriate atoms in the precursors to form a second substrate.

Method 200 continues with operation 225 where a second metallization surface is formed over the second substrate. In at least one embodiment, the second metallization is formed using a metalorganic chemical vapor deposition (MOCVD) process. In some embodiments, the second metallization surface is formed using molecular beam epitaxy (MBE), hydride vapor phase epitaxy (HVPE), Physical Vapor Deposition (PVD), Chemical Vapor Deposition (CVD), Atomic Layer Deposition (ALD), sputtering, spin-on coating or another suitable formation method.

Method 200 continues with operation 230 where a second side of the monolithic thermoelectric material is mechanically placed onto the second metallization surface. In various embodiments, the monolithic thermoelectric material includes the thermoelectric material, the second thermoelectric material, and the third thermoelectric material. In one or more embodiments, the monolithic thermoelectric material is electrically contacted to the second metallization surface by soldering or welding the third thermoelectric material to the second metallization surface.

One of ordinary skill in the art would recognize that operations are added or removed from method 200, in one or more embodiments. One of ordinary skill in the art would also recognize that an order of operations in method 200 is able to be changed, in some embodiments.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. An electric generator comprising:
a thermoelectric material over a first metallization surface, wherein the thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film; and
a second metallization surface over the thermoelectric material.

2. The electric generator of claim 1, wherein the thermoelectric material comprises a porosity ranging from 50% to 90%.

3. The electric generator of claim 1, wherein a thickness of the thermoelectric material ranges from approximately 1 micrometer to approximately 5 millimeters.

4. The electric generator of claim 1, further comprising the first metallization surface over a first substrate.

5. The electric generator of claim 1, further comprising a second substrate over the second metallization surface.

6. The electric generator of claim 1, wherein the polyimide film has a thermal conductivity ranging from approximately 0.1 W/m/K to approximately 1.5 W/m/K.

7. The electric generator of claim 1, further comprising a second thermoelectric material between the thermoelectric material and the first metallization surface, wherein the second thermoelectric material has a porosity less than the porosity of the thermoelectric material, and wherein the second thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film.

8. The electric generator of claim 7, wherein a thickness of the second thermoelectric material ranges from approximately 1 micrometer to approximately 5 millimeters.

9. The electric generator of claim 1, further comprising a third thermoelectric material between the thermoelectric material and the second metallization surface, wherein the third thermoelectric material has a porosity less than the porosity of the thermoelectric material, and wherein the third thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film.

10. The electric generator of claim 9, wherein a thickness of the third thermoelectric material ranges from approximately 1 micrometer to approximately 5 millimeters.

11. An electric generator comprising:
a thermoelectric material over a first metallization surface, wherein the thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film;
a second metallization surface over the thermoelectric material;
a second thermoelectric material between the thermoelectric material and the first metallization surface, wherein the second thermoelectric material has a porosity less than the porosity of the thermoelectric material, and wherein the second thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nano structured particles embedded in a base polymer, Bismuth telluride (Bi₂Te₃), or a polyimide film;
a third thermoelectric material between the thermoelectric material and the first metallization surface, wherein the third thermoelectric material has a porosity less than the porosity of the thermoelectric material, and wherein the third thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film;
the first metallization surface over a first substrate; and
a second substrate over the second metallization surface,
wherein the thermoelectric material comprises a porosity ranging from 50% to 90%,
wherein a thickness of the thermoelectric material ranges from approximately 1 micrometer to approximately 5 millimeters,
wherein the polyimide film has a thermal conductivity ranging from approximately 0.1 W/m/K to approximately 1.5 W/m/K,
wherein a thickness of the second thermoelectric material ranges from approximately 1 micrometer to approximately 5 millimeters,
wherein a thickness of the third thermoelectric material ranges from approximately 1 micrometer to approximately 5 millimeters.

12. An electric generator comprising:
a thermoelectric material over a first metallization surface, wherein the thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film;
a second metallization surface over the thermoelectric material;
a second thermoelectric material between the thermoelectric material and the first metallization surface, wherein the second thermoelectric material has a porosity less than the porosity of the thermoelectric material, and wherein the second thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nanostructured particles embedded in a base polymer, Bismuth telluride (Bi₂Te₃), or a polyimide film; and
a third thermoelectric material between the thermoelectric material and the first metallization surface, wherein the third thermoelectric material has a porosity less than the porosity of the thermoelectric material, and wherein the third thermoelectric material comprises at least one of poly(3,4-ethylenedioxythiophene):poly(styrenesulfonate) (PEDOT:PSS), tellurium-PEDOT:PSS (Te-PEDOT:PSS), Polydimethylsiloxane (PDMS), carbon nano structured particles embedded in a base polymer, Bismuth telluride (Bi₂Te₃), or a polyimide film, wherein the thermoelectric material comprises a porosity ranging from 50% to 90%,
wherein a thickness of the thermoelectric material ranges from approximately 1 micrometer to approximately 5 millimeters,
wherein the polyimide film has a thermal conductivity of 0.5 W/m/K or larger,
wherein a thickness of the second thermoelectric material ranges from approximately 1 micrometer to approximately 5 millimeters,
wherein a thickness of the third thermoelectric material ranges from approximately 1 micrometer to approximately 5 millimeters.

13. The electric generator of claim 12, further comprising the first metallization surface over a first substrate.

14. The electric generator of claim 13, further comprising a second substrate over the second metallization surface.

15. The electric generator of claim 1, wherein a monolithic thermoelectric material comprises the thermoelectric material, the second thermoelectric material, and the third thermoelectric material.

16. The electric generator of claim 11, wherein a monolithic thermoelectric material comprises the thermoelectric material, the second thermoelectric material, and the third thermoelectric material.

17. The electric generator of claim 12, wherein a monolithic thermoelectric material comprises the thermoelectric material, the second thermoelectric material, and the third thermoelectric material.
